(19) United States
(12) Patent Application Publication
(10) Pub. No.: US 2007/0278519 A1
(43) Pub. Date: Dec. 6, 2007

(54) Enhancement Depletion Field Effect Transistor Structure and Method of Manufacture

(75) Inventors: Pierre M.M. Baudet, Yerres (FR); Hassan Maher, Boissy-St-Leger (FR)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/575,521

(22) PCT Filed: Sep. 22, 2005
(86) PCT No.: PCT/IB05/53134

§ 371 Date: Mar. 19, 2007

(30) Foreign Application Priority Data
Sep. 24, 2004 (EP) 04300620.4

(51) Int. Cl. H01L 27/095; H01L 27/088

(52) U.S. Cl. 257/192; 438/172; 257/E27.06; 257/E27.068

(57) ABSTRACT

The invention relates to a transistor structure with both enhancement and depletion mode transistors. In order to allow good control over the manufacture of both transistors, a first Schottky layer (10) and a second Schottky layer (12) are used made of first and second semiconductor materials respectively. The first and second materials having band gaps of at least 0.5V. For an n-type transistor the second Schottky layer has a low conduction band discontinuity with the first Schottky layer. Both the first and the second Schottky layers are used as etch stops in the method for making the transistor. The transistor is preferably a HEMT.

The invention relates to a method of manufacture of enhancement-depletion type transistor structures, and the transistor structures thus made, and particularly to high electron mobility (HEMT) structures.

Enhancement—depletion technology combines enhancement-mode heterostructure field effect transistors (H-FETs) with depletion-mode heterostructure insulated gate H-FETs on the same substrate. The technology is applied in particular to high electron mobility (HEMT) FETs, including metamorphic HEMTs (MHEMTs) or pseudomorphic HEMTS (PHEMTs). In a HEMT, charge is transferred from a charge donor layer to an undoped channel layer. In PHEMTs, one or more layers have a different lattice constant to other layers resulting in straining which can improve some device characteristics.

The tight control of threshold voltages is important in such structures and etch stop layers may be used to control etching to achieve such tight control.

In particular, in a GaAs/AlGaAs/InGaAs/GaAs PHEMT structure the AlGaAs Schottky layer can be used as an etch stop layer of a chloride gas based dry etch to obtain a well-controlled depletion HEMT, and hence a well-controlled threshold voltage in the depletion HEMT.

An alternative structure is proposed in EP 119089. In this arrangement, an ED-HEMT having both enhancement and depletion FETs is formed. An undoped GaAs layer is formed on a semi-insulating substrate, a N-type AlGaAs layer is formed above the undoped GaAs layer, followed by a first GaAs layer, an AlGaAs layer, and a second GaAs layer. The AlGaAs layer is used as an etch stop during the step of etching the second GaAs layer at a location subsequently used to form the gate of the depletion-mode FET.

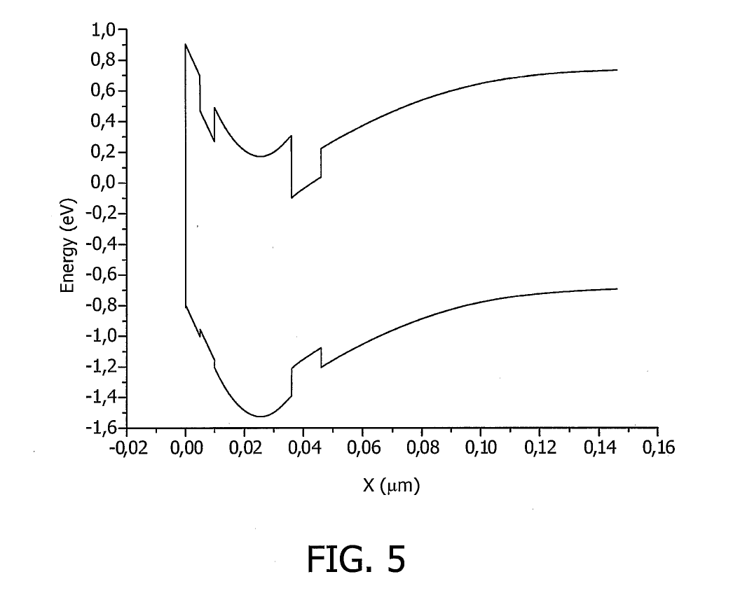

A band diagram of this structure is shown in FIG. 5.

Unfortunately, this structure includes the first GaAs layer under the gate of the depletion-mode FET, an extra layer compared with conventional structures that just use AlGaAs. The inventors have realised that this extra layer represents a deep potential well in the conduction band of the total device, which induces a high leakage current and low breakdown voltage. Further, at positive gate voltages, the GaAs layer may not be depleted thus degrading device performance.

U.S. Pat. No. 5,739,557 describes a similar approach, which uses a GaAs/AlAs/GaAs/AlAs structure above the active layer. The AlAs layers are used as etch stop layers.

Accordingly, there remains a need for a manufacturing technology for ED-HEMTs that achieves good static and dynamic performances.

According to the invention there is provided a method of manufacturing an n-type or p-type enhancement-depletion field effect transistor structure having an enhancement field effect transistor in an enhancement region and a depletion field effect transistor in a depletion region, the method comprising the steps of:

forming a semiconductor channel layer on a substrate;

forming a first Schottky layer of semiconductor on the semiconductor channel layer;

forming a second Schottky layer of semiconductor on the first Schottky layer,

forming a cap layer over the second Schottky layer;

etching in the depletion region a depletion gate opening in the cap layer using the second Schottky layer as an etch stop and forming a depletion gate (24) on the second Schottky layer in the depletion gate opening; and

etching in the enhancement region of the field effect transistor an enhancement gate opening through the cap layer and the second Schottky layer using the first Schottky layer as an etch stop, and forming an enhancement gate on the first Schottky layer in the enhancement gate opening,

wherein the first Schottky layer is a single layer of a first semiconductor material, the second Schottky layer is a single layer of a second semiconductor material, different to the first and selectively etchable with respect to the first material so that the step of etching in the enhancement region can use the first Schottky layer as an etch stop, and wherein the conduction band discontinuity in the first and second semiconductor materials does not exceed 0.5 eV.

By using single layers as the first and second Schottky layers the process is made as simple as possible.

In a second aspect there is provided a method of manufacturing an n- type or p-type enhancement-depletion field effect transistor structure having an enhancement field effect transistor in an enhancement region and a depletion field effect transistor in a depletion region, the method comprising the steps of:

forming a semiconductor channel layer on a substrate;

forming a first semiconductor Schottky layer comprising a first semiconductor material on the semiconductor channel layer;

forming a second Schottky layer comprising a second semiconductor material on the first Schottky layer, wherein the second semiconductor material has a conduction band discontinuity less than 0.5 V with the first semiconductor material;

forming a cap layer over the second Schottky layer;

etching in the depletion region a depletion gate opening in the cap layer using the second Schottky layer as an etch stop and forming a depletion gate on the second Schottky layer in the depletion gate opening; and

etching in the enhancement region of the field effect transistor an enhancement gate opening through the cap layer and the second Schottky layer using the first Schottky layer as an etch stop, and forming an enhancement gate on the first Schottky layer in the enhancement gate opening,

wherein the first and second Schottky layers are formed of first and second semiconductor materials, one of the first and second semiconductor materials is either InGaAs or AlGaAs (preferably with an Al content no higher than 35%), and the other of the first and second semiconductor materials is GalnP.

These choices of materials allow high quality ohmic contacts with reduced series resistances, and in particular they allow for high temperature reliablity of the structure thus formed. Such problems appear in particular when using materials with a high concentration of Al, for example AlAs. Another problem which may occur in such cases is lateral oxidation.

One of the first and second layers may be fully formed of the first material and the other of the first and second layers may be fully formed of the second semiconductor material.

Alternatively, the first Schottky layer may include a layer of the first semiconductor material and a layer of second semiconductor material as an etch stop layer over the layer of the first semiconductor material, and the second Schottky layer includes a layer of the first semiconductor material and a layer of the second semiconductor material as an etch stop layer over the layer of the first semiconductor material.

The depletion FET threshold voltage is determined by the full thickness of the first and second Schottky layers whereas the enhancement FET threshold voltage is determined by the thickness of the first layer only.

The use of a second layer with a low conduction band discontinuity with the first layer leads to a highly controllable process which results in a good performance D-HEMT. Preferably, the step is below 0.3V, further preferably below 0.1V.

In a preferred embodiment, the use of the Schottky layers themselves as the etch stop layers avoids the need for superfluous layers reducing the performance of the device. Further, if additional etch stop layers were to be introduced this would increase the manufacturing complexity of the device, and the method according to the invention avoids the need for such additional layers.

The Schottky layers preferably include layers with band gaps above 1V, further preferably above 1.5V.

The transistor preferably includes a thin doped layer in the first Schottky layer for providing a high electron mobility channel. The thin doped layer may be a delta doped layer.

A preferred choice of materials for the first and second Schottky layers is GalnP and AlGaAs, which both have sufficiently high band gaps and which give a low step in the conduction band.

The first Schottky layer may be GaInP and the second Schottky layer AlGaAs, or vice versa.

Alternatively, the first Schottky layer may be InGaAs and the second Schottky layer GaInP, or vice versa. Such a choice of materials benefically avoids aluminium.

As will be appreciated, one of the etching steps uses InGaAs as the etch stop and one of the etching steps uses GaInP.

The step of etching using GaInP as an etch stop may use an etchant comprising ammonium hydroxide and hydrogen peroxide.

The step of etching using AlGaAs as an etch stop may use a wet or chlorine based dry etch.

The channel layer may be of InGaAs.

The cap may be of GaAs.

The first Schottky layer may include an etch stop layer on a first semiconductor material layer, and the second Schottky layer an etch stop layer on a second semiconductor material layer.

In another aspect, the invention relates to an enhancement-depletion field effect transistor structure having an enhancement field effect transistor in an enhancement region and a depletion field effect transistor in a depletion region, comprising:

a semiconductor channel layer on a substrate;

a first Schottky layer comprising a first semiconductor material on the semiconductor channel layer;

a second Schottky layer comprising a second semiconductor material on the first Schottky layer, the first and second materials having bandgaps of at least 0.5V; wherein the second semiconductor material has a conduction band discontinuity not greater than 0.5 eV with the first semiconductor material;

a cap layer over the second Schottky layer;

a depletion contact opening through the cap layer extending to the second Schottky layer in the depletion region and a depletion contact to the second Schottky layer in the depletion contact opening; and

an enhancement contact opening through the cap layer and the second Schottky layer extending to the first Schottky layer, and an enhancement contact to the first Schottky layer in the enhancement contact opening;

wherein the first Schottky layer is a single layer of a first semiconductor material, the second Schottky layer is a single layer of a second semiconductor material, different to the first and selectively etchable with respect to the first material, and wherein the conduction band discontinuity in the first and second Schottky layer materials does not exceed 0.5 eV.

In another aspect, the invention relates to an enhancement-depletion field effect transistor structure having an enhancement field effect transistor in an enhancement region and a depletion field effect transistor in a depletion region, comprising:

a semiconductor channel layer on a substrate;

a first Schottky layer comprising a first semiconductor material on the semiconductor channel layer;

a second Schottky layer comprising a second semiconductor material on the first Schottky layer, the first and second materials having bandgaps of at least 0.5V; wherein the second semiconductor material has a conduction band discontinuity not greater than 0.5 eV with the first semiconductor material;

a cap layer over the second Schottky layer;

a depletion contact opening through the cap layer extending to the second Schottky layer in the depletion region and a depletion contact to the second Schottky layer in the depletion contact opening; and

an enhancement contact opening through the cap layer and the second Schottky layer extending to the first Schottky layer, and an enhancement

wherein the first and second Schottky layers are formed of first and second semiconductor materials, one of the first and second semiconductor materials is either InGaAs or AlGaAs, and the other of the first and second semiconductor materials is GaInP.

For a better understanding of the invention, embodiments will be described with reference to the accompanying drawings, in which:

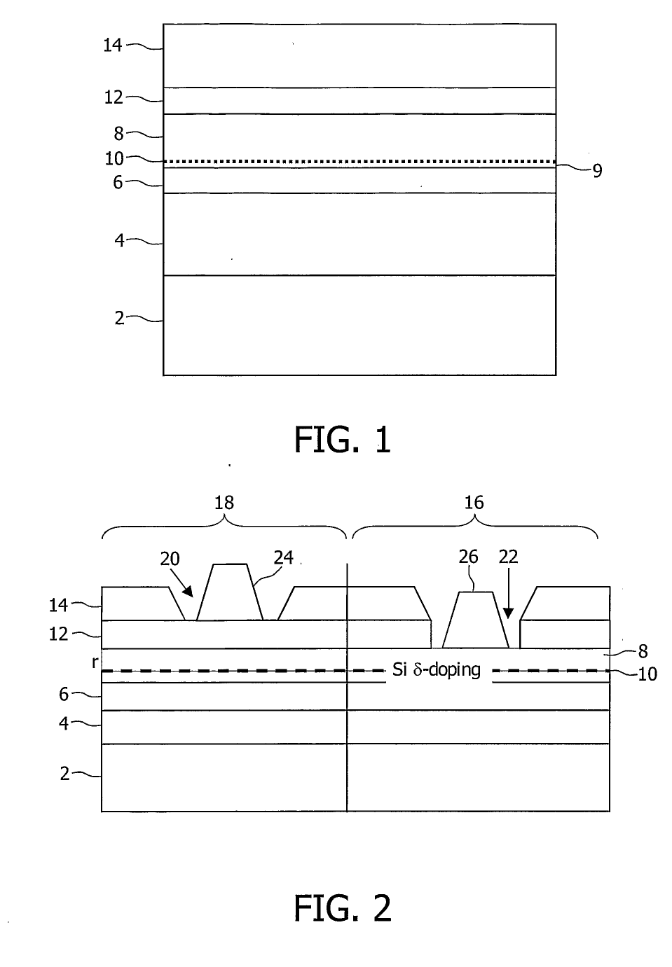

FIG. 1 is a cross-sectional view of the semiconductor layers used in a first embodiment of the invention;

FIG. 2 is a cross sectional view of the first embodiment of the invention;

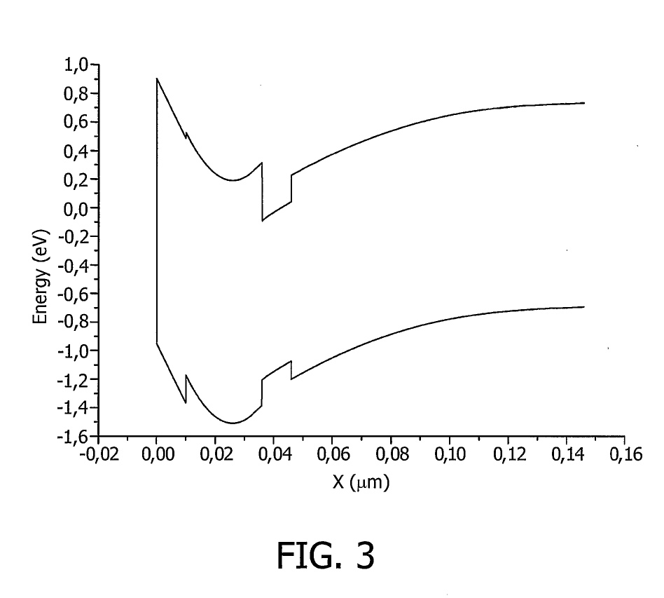

FIG. 3 is a band diagram of the first embodiment of the invention;

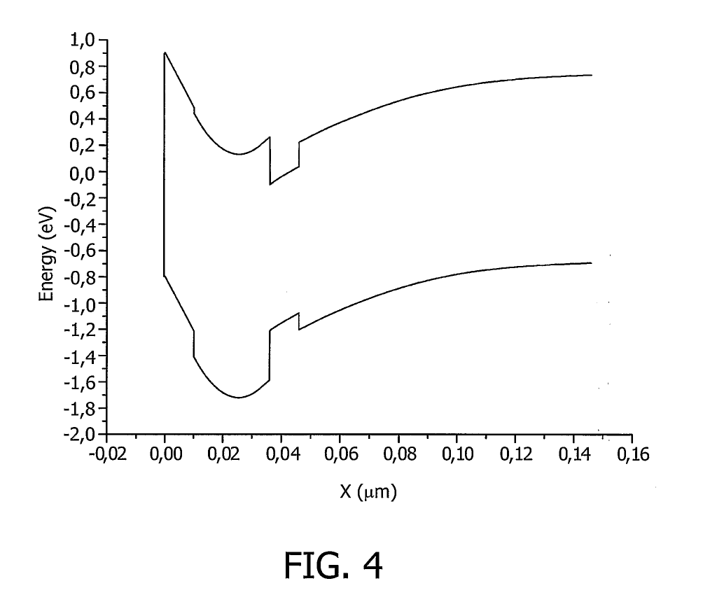

FIG. 4 is a band diagram of the second embodiment of the invention;

FIG. 5 is a band diagram of a prior art arrangement;

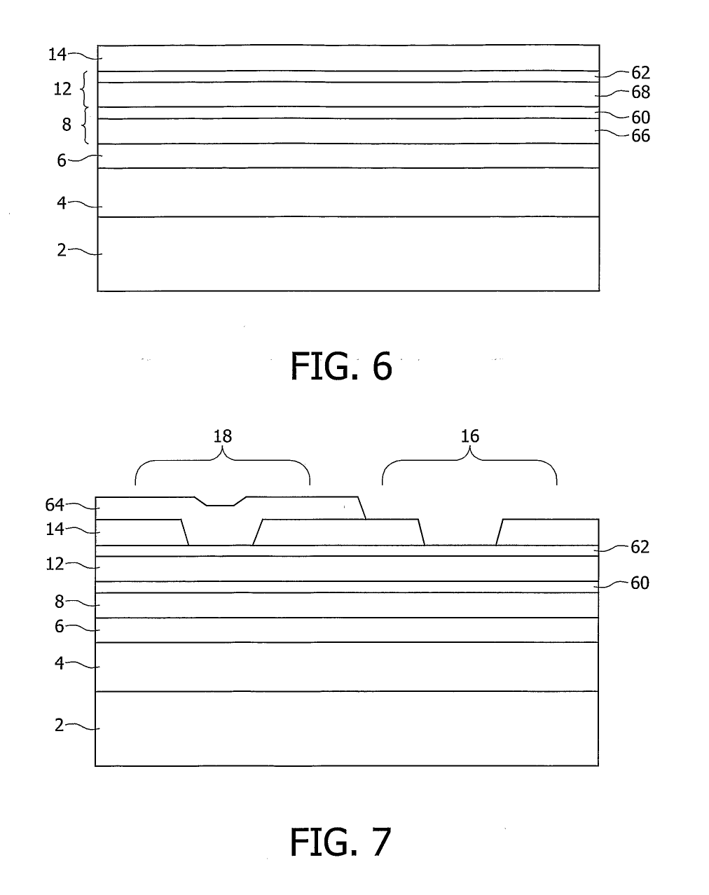

FIG. 6 is a cross sectional view of the semiconductor layers in a third embodiment of the invention;

FIG. 7 is a cross-sectional view of an intermediate stage in the manufacture of a semiconductor device according to the third embodiment; and

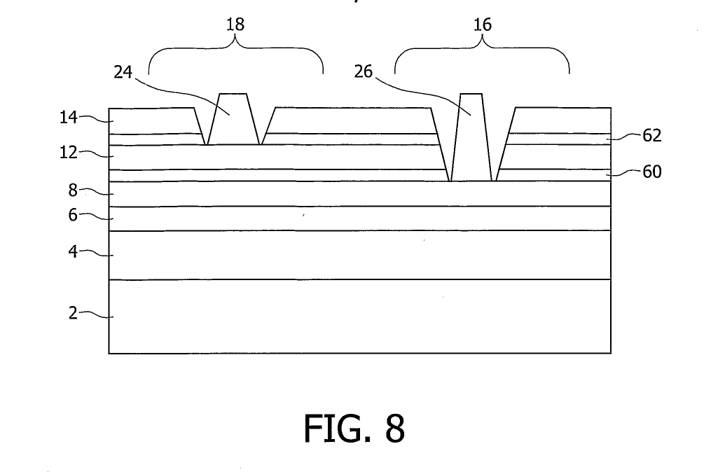

FIG. 8 is a cross sectional view of the third embodiment of the invention.

Referring to FIG. 1, a semi-insulating GaAs substrate 2 has a GaAs buffer layer 4 formed upon it to a thickness of about 50 nm.

Next, an undoped In_{0.22}Ga_{0.78}As channel layer 6 is formed on the buffer layer 4 to a thickness of about 10 nm.

Two Schottky layers are then formed on the buffer layer. The first is first Schottky layer 8 of Al_{0.22}Ga_{0.78}As, which is largely undoped except for a thin doped layer or δ-doped layer 10 which is highly doped with Si formed within the first Schottky layer 8 spaced from the channel layer. The part of the first Schottky layer 8 between the thin doped layer 10 and the channel layer 6 constitutes a thin spacer layer 9. The total thickness of the first Schottky layer is approximately 23 nm.

The second Schottky layer 12 is about 7.5 nm of undoped Ga_{0.51}In_{0.49}P. This layer is followed by cap layer 14 of GaAs to a thickness of 55 nm. The GaAs cap is heavily doped n+.

The AlGaAs has a lattice constant that is slightly mismatched to the GaAs and the InGaAs channel has a significant mismatch to the GaAs creating strain in the channel layer. The transistor structure described is accordingly a PHEMT.

Those skilled in the art will realise that the specific compositions of the layers can be varied as required, as can the specific thicknesses of the different layers. In particular, by varying the thicknesses and compositions of the layers the amount of strain can be varied. The layer described as undoped may in practice be lightly doped.

The gates of the enhancement and depletion layer FETs are then formed, as will now be described with reference to FIG. 2. The enhancement FET is formed in enhancement FET region 16 and the depletion FET in depletion FET region 18.

In the preferred embodiment, a first patterning step is used to define the gates in both the depletion FET and the enhancement FET. This can be a fine (high resolution) patterning step using for example electron beam lithography. Then, the cap layer is etched using the GaInP second Schottky layer as an etch stop, to define openings for both the enhancement and depletion FETs. Next, a protection layer is used to protect the depletion FET. The patterning of this layer can be coarse. Then, the second Schottky layer is etched using the first Schottky layer 8 as an etch stop, for example using a chlorine based dry etch. In this way, only a single high resolution patterning step is required.

The first etching step using the GaInP second Schottky layer as an etch stop may be carried out by a wet etch using a mixture of ammonium hydroxide and hydrogen peroxide (NH₄OH—H₂O₂). The second etching step using the GaInP first Schottky layer 8 as the etch stop may be done using a chlorine based dry etch.

Then, gates are formed in the gate openings 20,22 forming depletion gate 24 in the depletion gate opening 20 and enhancement gate 26 in the enhancement gate opening 22.

The device is then finished in a manner well known in the art which will accordingly not be described further.

The band diagram in the depletion region 18 is shown in FIG. 3. Note the low conduction band discontinuity between the first and second Schottky layers 12, 14. This should be compared with the large discontinuities in the prior art structure of EP 119 089 and in particular the band diagram of FIG. 5

The delta-doping 10 provides a channel region at the heterostructure interface between the channel layer 6 and the first Schottky layer 10, as can be seen in FIG. 2 where the 0V Fermi level is above the conduction band edge only in this region. The channel region may have a high mobility, making the transistor a HEMT.

Thus, the invention provides a structure which avoids the disadvantages of the prior art, and in particular avoids the risk in prior art FIG. 5 that the GaAs well can become non-depleted for some values of gate voltage. The leakage current is also lowered. This is achieved using a straightforward manufacturing method which allows precise control of the threshold voltages in both the enhancement and depletion mode transistors.

The first embodiment has the advantage of simplicity and no additional layers are required other than the first and second Schottky layers of the first and second materials. Thus, this embodiment delivers a major gain in the time and manufacturing cost using a minor change to the standard process.

The band diagram of a second embodiment of the invention is shown in FIG. 4, which uses the same method and layers except where described below.

In the second embodiment, the first Schottky layer 8 is of GaInP and the second Schottky layer 10 is of AlGaAs. Accordingly, a wet etch using a mixture of ammonium hydroxide and hydrogen peroxide (NH₄OH—H₂O₂) is used to form the enhancement gate opening 22 and a chlorine based dry etch to form the depletion gate opening 20.

Inspection of the band diagram reveals the same low discontinuity in the conduction band and the same benefits as the first embodiment.

A third embodiment will now be described with reference to FIGS. 6 to 8.

In the third embodiment, the first and second Schottky layers are not formed of a single layer of a single semiconductor material, but include multiple layers. In the particular embodiment described, the first Schottky layer 8 includes a first band gap layer 66 and a first etch stop layer 60. The second Schottky layer 12 includes a second band gap layer 68 and a second etch stop layer 62 on top of the second band gap layer 68. The cap layer 14 is accordingly on top of the second etch stop layer 62, as illustrated in FIG. 6.

In this arrangement, the etch stop layers 62,60 can be of InGaP and the first and second material layers 8,12 can both be of AlGaAs.

In alternative embodiments, other choices can be made for example with the etch stop layers 62,60 of AlGaAs and the first and second material layers 8,12 or InGaP. The materials need to have etch selectivity as well as a small discontinuity in the conduction band to avoid poor transistor performance.

Further, by avoiding the use of AlAs, the problems mentioned above for this material can be avoided.

Processing of the layers proceeds in a similar way to the first embodiment.

After forming the layers, a gate pattern is formed using either electron beam or photo-lithography for the gates of both the depletion 18 and the enhancement 16 FETs.

Next, the cap layer 14 is selectively etched down to the top of the second Schottky layer 12, namely the top of the second etch stop layer 62.

A protection layer 64 (FIG. 7) is used to cover the depletion HEMT 18. The patterning of the protection layer 64 need not be fine.

Next, the second etch-stop layer 62 and the second band-gap layer 68 are etched down to the first etch stop layer. The protection layer 64 is removed Then, both etch stop layers 60,62 are etched away where they are exposed in the gate openings.

Gates 24,26 are then formed on the first and second Schottky layers 8, 10 in the depletion and enhancement FETs respectively. A lift off process is then carried out to arrive at the device shown in FIG. 8.

The advantage of this approach is that the etch stop layers 60,62 are removed from both the Schottky layers 8, 12 immediately before depositing the gates. The etch stop layers 60,62 thus act as protection layers. The Schottky layers 8, 12 can in this way have a clean surface forming a good barrier with the gates 24,26. If required, an additional cleaning step can be provided immediately before forming the gates to ensure a clean surface. Thus, the third embodiment allows an improved Schottky barrier for both the FETs 18,16, improving in particular device uniformity. In contrast, in the first and second embodiments, some photoresist residues may be left at the surface.

The skilled person will be aware of other suitable materials and etchants from the field of semiconductor processing and such other materials and etchants may be used if required. In particular, the invention is not limited to GaAs substrates or the particular semiconductors and etchants described above.

1. A method of manufacturing an enhancement-depletion field effect transistor structure having an enhancement field effect transistor in an enhancement region (16) and a depletion field effect transistor in a depletion region (18), the method comprising the steps of:
forming a semiconductor channel layer (6) on a substrate (2);
forming a first Schottky layer (8) of semiconductor on the semiconductor channel layer;
forming a second Schottky layer (12) of semiconductor on the first Schottky layer, forming a cap layer (14) over the second Schottky layer;
etching in the depletion region (18) a depletion gate opening (20) in the cap layer using the second Schottky layer structure (12) as an etch stop and forming a depletion gate (24) on the second Schottky layer (12) in the depletion gate opening (20); and
etching in the enhancement region (16) of the field effect transistor an enhancement gate opening (22) through the cap layer (14) and the second Schottky layer (12) using the first Schottky layer (8) as an etch stop, and forming an enhancement gate (26) on the first Schottky layer in the enhancement gate opening (22),
wherein the first Schottky layer (8) is a single layer of a first semiconductor material, the second Schottky layer (12) is a single layer of a second semiconductor material, different to the first and selectively etchable with respect to the first material so that the step of etching in the enhancement region (16) can use the first Schottky layer (8) as an etch stop, and wherein the conduction band discontinuity in the first and second Schottky layer materials does not exceed 0.5 eV.

2. A method according to claim 1 further comprising defining a gate opening (20,22) in both of the enhancement and depletion regions (18,16) in a single patterning step.

3. A method according to claim 2 where the steps of etching include, in the following order:
etching in both the depletion region (18) and the enhancement region (16) a gate opening (20,22) through the cap layer (14) using the second Schottky layer (12) as an etch stop;
covering the depletion region (18) with a protection film (64);
etching in the enhancement region (16) of the field effect transistor an enhancement gate opening (22) through the cap layer (14) and the second Schottky layer (12) using the first Schottky layer (8) as an etch stop; and
forming a depletion gate (24) on the second Schottky layer (12) in the depletion gate opening (20); and an enhancement gate (26) on the first Schottky layer (8) in the enhancement gate opening (22).

4. A method of manufacturing an enhancement-depletion field effect transistor structure having an enhancement field effect transistor in an enhancement region (16) and a depletion field effect transistor in a depletion region (18), the method comprising the steps of:
forming a semiconductor channel layer (6) on a substrate (2);
forming a first semiconductor Schottky layer structure (8) on the semiconductor channel layer;
forming a semiconductor second Schottky layer structure (12) on the first Schottky layer structure, wherein the conduction band discontinuity in the first and second Schottky layer structures does not exceed 0.5 eV;
forming a cap layer (14) over the second Schottky layer;
etching in the depletion region (18) a depletion gate opening (20) in the cap layer using the second Schottky layer structure (12) as an etch stop and forming a depletion gate (24) on the second Schottky layer structure (12) in the depletion gate opening (20); and
etching in the enhancement region (16) of the field effect transistor an enhancement gate opening (22) through the cap layer (14) and the second Schottky layer structure (12) using the first Schottky layer structure (8) as an etch stop, and forming an enhancement gate (26) on the first Schottky layer in the enhancement gate opening (22);
wherein the first and second Schottky layers are formed of first and second semiconductor materials, one of the first and second semiconductor materials is either InGaAs or AlGaAs, and the other of the first and second semiconductor materials is GaInP.

5. A method according to claim 4 wherein the first Schottky layer includes a layer of the first semiconductor material (66) and a layer of second semiconductor material (62) as an etch stop layer (60) over the layer fo the first semiconductor material, and the second Schottky layer includes a layer of the first semiconductor material and a layer of the second semiconductor material (62) as an etch stop layer (62) over the layer of the first semiconductor material.

6. A method according to claim 1 further comprising a thin doped layer (10) in the first Schottky layer (8) for supplying carriers to form a channel at the boundary between the channel layer (6) and the first Schottky layer (8).

7. A method according to claim 1 wherein the first semiconductor material is GaInP and the second semiconductor material is AlGaAs respectively.

8. A method according to claim 1 wherein the first semiconductor material is GaInP and the second semiconductor material is InGaAs.

9. A method according to claim 1 wherein the first semiconductor material is InGaAs and the second semiconductor material is GaInP.

10. A method according to claim 7 wherein the step of etching using GaInP as an etch stop uses an etchant comprising ammonium hydroxide and hydrogen peroxide.

11. A method according to claim 7 when dependent on claim 8 wherein the step of etching using AlGaAs as an etch stop uses a wet or chlorine based dry etch.

12. A method according to claim 1 wherein the channel layer (6) is of InGaAs.

13. A method according to claim 1 wherein the cap (14) is of GaAs.

14. An enhancement-depletion field effect transistor structure having an enhancement field effect transistor in an enhancement region (16) and a depletion field effect transistor in a depletion region (18), comprising:
a semiconductor channel layer (6) on a substrate (2);
a first Schottky layer (8) comprising a first semiconductor material on the semiconductor channel layer (6);
a second Schottky layer (12) comprising a second semiconductor material on the first Schottky layer (8), the first and second materials having bandgaps of at least 0.5V; wherein the second semiconductor material has a conduction band discontinuity not greater than 0.5 eV with the first semiconductor material;
a cap layer (14) over the second Schottky layer (12);
a depletion contact opening (20) through the cap layer (14) extending to the second Schottky layer (12) in the depletion region (18) and a depletion contact (24) to the second Schottky layer (12) in the depletion contact opening (20); and
an enhancement contact opening (22) through the cap layer (14) and the second Schottky layer (12) extending to the first Schottky layer (8), and an enhancement contact (26) to the first Schottky layer (8) in the enhancement contact opening (22);
wherein the first Schottky layer (8) is a single layer of a first semiconductor material, the second Schottky layer (12) is a single layer of a second semiconductor material, different to the first and selectively etchable with respect to the first material, and wherein the conduction band discontinuity in the first and second Schottky layer materials does not exceed 0.5 eV.

15. An enhancement-depletion field effect transistor structure having an enhancement field effect transistor in an enhancement region (16) and a depletion field effect transistor in a depletion region (18), comprising
effect transistor in a depletion region (18), comprising:
a semiconductor channel layer (6) on a substrate (2);
a first Schottky layer (8) comprising a first semiconductor material on the semiconductor channel layer (6);
a second Schottky layer (12) comprising a second semiconductor material on the first Schottky layer (8), the first and second materials having bandgaps of at least 0.5V; wherein the second semiconductor material has a conduction band discontinuity not greater than 0.5 eV with the first semiconductor material;
a cap layer (14) over the second Schottky layer (12);
a depletion contact opening (20) through the cap layer (14) extending to the second Schottky layer (12) in the depletion region (18) and a depletion contact (24) to the second Schottky layer (12) in the depletion contact opening (20); and
an enhancement contact opening (22) through the cap layer (14) and the second Schottky layer (12) extending to the first Schottky layer (8), and an enhancement contact (26) to the first Schottky layer (8) in the enhancement contact opening (22);
wherein the first and second Schottky layers (8,12) are formed of first and second semiconductor materials, one of the first and second semiconductor materials is either InGaAs or AlGaAs, and the other of the first and second semiconductor materials is GaInP.
wherein the first and second Schottky layers (8,12) are formed of first and second semiconductor materials, one of the first and second semiconductor materials is either InGaAs or AlGaAs, and the other of the first and second semiconductor materials is GaInP.

16. A semiconductor device according to claim 15 wherein the first and second semiconductor layers are each single layers.

17. A semiconductor device according to claim 15 wherein the first Schottky layer includes a layer of the first semiconductor material (66) and a layer of second semiconductor material (62) as an etch stop layer (60) over the layer fo the first semiconductor material, and the second Schottky layer includes a layer of the first semiconductor material and a layer of the second semiconductor material (62) as an etch stop layer (62) over the layer of the first semiconductor material.
